(19) United States
(12) Patent Application Publication
(10) Pub. No.: US 2026/0191021 A1
(43) Pub. Date: Jul. 2, 2026

(54) SEMICONDUCTOR PACKAGE

(71) Applicant: SAMSUNG ELECTRONICS CO., LTD., Suwon-si (KR)

(72) Inventor: Won CHOI, Suwon-si (KR)

(73) Assignee: SAMSUNG ELECTRONICS CO., LTD., Suwon-si (KR)

(21) Appl. No.: 19/278,102

(22) Filed: Jul. 23, 2025

(30) Foreign Application Priority Data
Dec. 27, 2024 (KR) 10-2024-0199117

(51) Int. Cl. H01L 23/544; H01L 23/00; H01L 23/498

(52) U.S. Cl. CPC H10W 46/00; H10W 42/121; H10W 70/635; H10W 46/301; H10W 72/072; H10W 72/222; H10W 72/285; H10W 90/724

(57) ABSTRACT

A semiconductor package according to an example embodiment of the present disclosure includes: a package substrate including a substrate body and a conductive pattern; a semiconductor chip on the package substrate, and including a chip body and a connection bump, the connection bump including a pillar and a solder; an encapsulant; and connection conductors, and the conductive pattern includes an alignment-inducing structure, and the alignment-inducing structure includes: a first indentation portion; a second indentation portion spaced apart from the first indentation portion in a longitudinal direction of the conductive pattern; and a center portion between the first indentation portion and the second indentation portion, and the solder covers at least portions of each of an upper surface and side surfaces of the center portion and fills at least a portion of a space indented by each of the first indentation portion and the second indentation portion.

### CROSS-REFERENCE TO RELATED APPLICATION(S)

This application claims benefit of priority to Korean Patent Application No. 10-2024-0199117 filed on Dec. 27, 2024, in the Korean Intellectual Property Office, the disclosure of which is incorporated herein by reference in its entirety.

### BACKGROUND

The present disclosure relates to a semiconductor package.

As electronic devices become lighter and higher performance, the development of miniaturized and high-performance semiconductor chips is required. Semiconductor chips may be mounted on a package substrate through connection bumps, and may receive power from a package substrate or transmit signals to the package substrate through a conductive pattern of the package substrate. Research has been conducted to prevent misalignment between the connection bumps of semiconductor chips and the conductive pattern of the package substrate.

### SUMMARY

An aspect of the present disclosure is to provide a semiconductor package with improved reliability by preventing misalignment of semiconductor chips on a package substrate.

A semiconductor package according to example embodiments may include: a package substrate including a substrate body and a conductive pattern on an upper surface of the substrate body; a semiconductor chip on the package substrate, and including a chip body and a connection bump below the chip body, the connection bump including a pillar and a solder below the pillar; an encapsulant surrounding the semiconductor chip on the package substrate; and connection conductors below the package substrate and electrically connected to the conductive pattern, the conductive pattern may include an alignment-inducing structure overlapping the semiconductor chip, wherein the alignment-inducing structure may include: a first indentation portion indented on a first side surface of the conductive pattern; a second indentation portion indented on a second side surface of the conductive pattern opposite to the first side surface, and spaced apart from the first indentation portion in a longitudinal direction of the conductive pattern; and a center portion between the first indentation portion and the second indentation portion, and the solder may cover at least portions of each of an upper surface and side surfaces of the center portion and may be disposed in at least a portion of a space indented by each of the first indentation portion and the second indentation portion.

A semiconductor package according to example embodiments may include: a semiconductor chip including a connection bump below a lower surface; a package substrate below the semiconductor chip, and including a conductive pattern extending in a horizontal direction; and an encapsulant surrounding the semiconductor chip on the package substrate, and the conductive pattern may further include an alignment-inducing structure in contact with the connection bump, and alignment-inducing structure may include: a center portion having a first width; and an indentation portion including a portion having a width less than the first width, and a portion of the indentation portion may be in contact with the encapsulant.

A semiconductor package according to example embodiments may include: a substrate body; a plurality of conductive patterns on an upper surface of the substrate body and including an alignment-inducing structure; a semiconductor chip on the plurality of conductive patterns and electrically connected to the plurality of conductive patterns through a plurality of connection bumps; and connection conductors below the substrate body, and the plurality of conductive patterns may include a first type conductive pattern in which one end thereof is disposed in a region overlapping the semiconductor chip, and a second type conductive pattern extending by intersecting a region overlapping the semiconductor chip, the first type conductive pattern may include the alignment-inducing structure disposed adjacently to the one end, the second type conductive pattern may include two or more alignment-inducing structures disposed in a portion intersecting the region overlapping the semiconductor chip, each of the plurality of connection bumps may be in contact with the alignment-inducing structure of the first type conductive pattern or the second type conductive pattern, and the alignment-inducing structure may include a pair of indentation side surfaces disposed to be misaligned from each other on both side surfaces opposing each other in a lateral direction of the plurality of conductive patterns.

According to example embodiments of the present disclosure, a conductive pattern having an alignment-inducing structure may be included, thereby providing a semiconductor package for preventing misalignment of a semiconductor chip and having improved reliability.

Advantages and effects of the present application are not limited to the foregoing content and may be more easily understood in the process of describing a specific example embodiment of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1A is a schematic plan view illustrating a semiconductor package according to example embodiments;

FIG. 1B is a schematic cross-sectional view illustrating a semiconductor package according to example embodiments;

FIG. 1C is a schematic cross-sectional view illustrating a semiconductor package according to example embodiments;

FIG. 2A is a schematic enlarged plan view illustrating a semiconductor package according to example embodiments;

FIG. 2B is a schematic cross-sectional enlarged view illustrating a semiconductor package according to example embodiments;

FIG. 2C is a schematic enlarged plan view illustrating a semiconductor package according to example embodiments;

FIG. 3 is a schematic perspective view illustrating an alignment-inducing structure of a conductive pattern according to example embodiments;

FIGS. 4 to 7 are schematic plan enlarged views illustrating a semiconductor package according to example embodiments;

FIGS. 8A, 9A, 10A, 11A and 12 are cross-sectional views illustrating a method of manufacturing a semiconductor package according to example embodiments of the present disclosure according to a process sequence; and

FIGS. 8B, 9B, 10B, and 11B are enlarged plan views illustrating a method of manufacturing a semiconductor package according to example embodiments of the present disclosure according to a process sequence.

### DETAILED DESCRIPTION

Hereinafter, example embodiments of the present disclosure will be described with reference to the accompanying drawings. Hereinafter, it may be understood that the expressions such as “on,” “above,” “upper,” “below”, “beneath,” “lower,” and “side surface” merely indicated based on drawings unless otherwise stated.

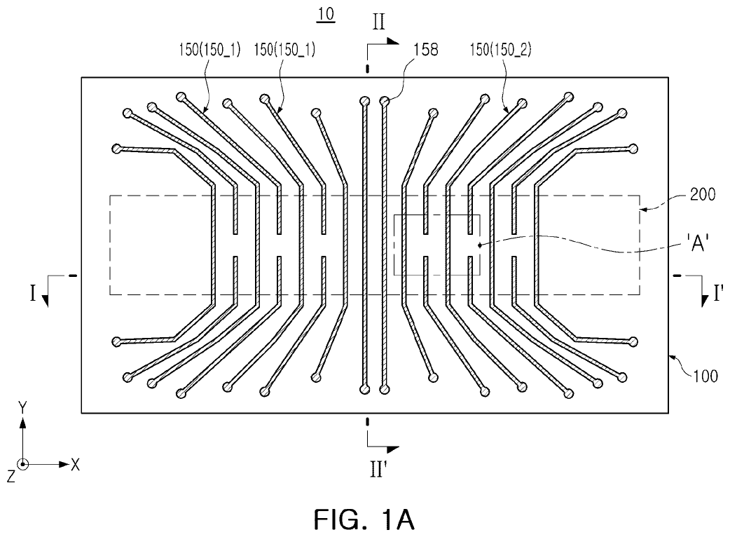

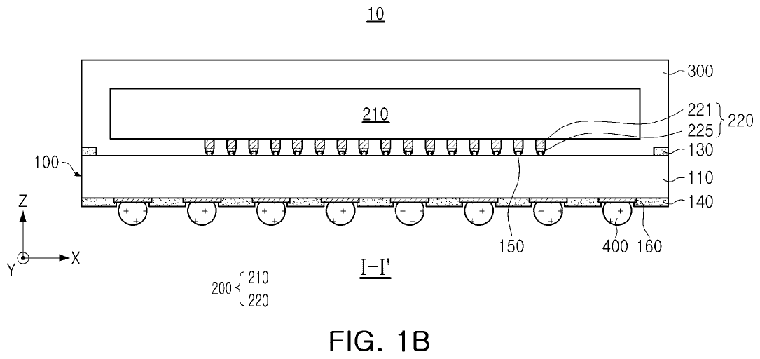

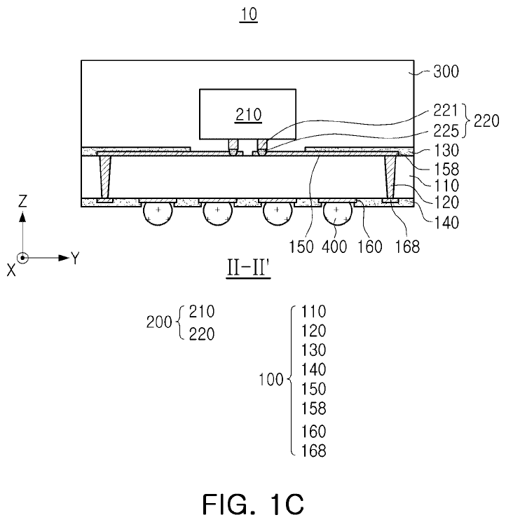

FIG. 1A is a schematic plan view illustrating a semiconductor package according to example embodiments.

FIG. 1B is a schematic cross-sectional view illustrating a semiconductor package according to example embodiments. FIG. 1B is a schematic cross-sectional view taken along cutting line I-I′ of the semiconductor package 10 of FIG. 1A.

FIG. 1C is a schematic cross-sectional view illustrating a semiconductor package according to example embodiments. FIG. 1C is a schematic cross-sectional view taken along the cutting line II-II′ of the semiconductor package 10 of FIG. 1A.

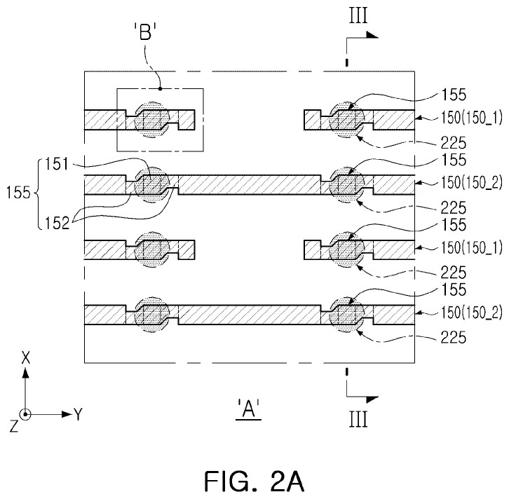

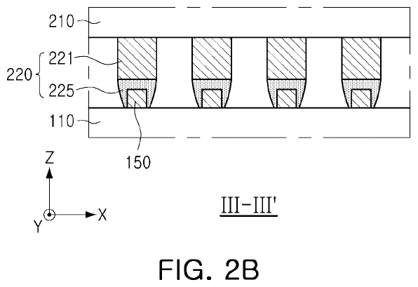

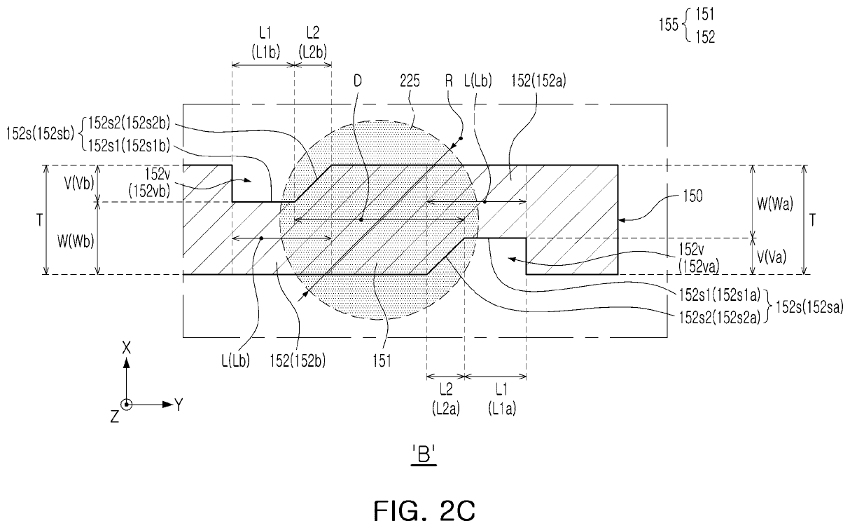

FIG. 2A is a schematic enlarged plan view illustrating a semiconductor package according to example embodiments. FIG. 2A is an enlarged view of region ‘A’ of the semiconductor package 10 of FIG. 1A.

FIG. 2B is an enlarged cross-sectional view schematically illustrating a semiconductor package according to example embodiments. FIG. 2B is a schematic cross-sectional view taken along the cutting line III-III′ of the semiconductor package 10 of FIG. 2A.

FIG. 2C is a schematic enlarged plan view illustrating a semiconductor package according to example embodiments. FIG. 2C is an enlarged view of region ‘B’ of the semiconductor package 10 of FIG. 2A.

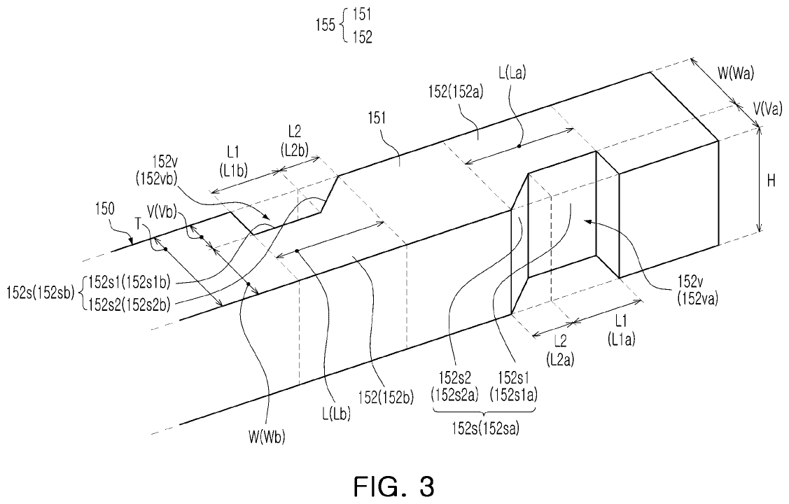

FIG. 3 is a schematic perspective view illustrating an alignment-inducing structure of a conductive pattern according to example embodiments. In FIG. 3, for convenience of description, other components except for the conductive pattern 150 are omitted and illustrated.

Referring to FIGS. 1A to 3, a semiconductor package 10 may include a package substrate a semiconductor chip 200, an encapsulant 300, and connection conductors 400.

The package substrate 100 is a support substrate on which the semiconductor chip 200 is mounted, and may be a semiconductor package substrate including a printed circuit board (PCB), a ceramic substrate, a glass substrate, and a tape interconnection board. For example, the package substrate 100 may be a one-sided PCB, a double-sided PCB, or a multilayer PCB. The package substrate 100 may include a substrate body 110, connection vias 120, an upper protective layer 130, a lower protective layer 140, and conductive patterns 150.

The substrate body 110 may have an upper surface extending in an X-direction and a Y-direction, and may have a lower surface opposing the upper surface. The semiconductor chip 200 may be mounted on an upper surface of the substrate body 110. The substrate body 110 may include an insulating material protecting the connection vias 120, for example, a thermosetting resin such as an epoxy resin, a thermoplastic resin such as a polyimide, or a prepreg including an inorganic filler or/and glass fiber (Glass Fiber, Glass Cloth or Glass Fabric), Ajinomoto Build-up Film (ABF), and Frame Retardant 4 (FR4).

The connection vias 120 may electrically connect the conductive patterns 150 and lower pads 160 within the substrate body 110. The connection vias 120 may be in contact with a via connection structure 158 of the conductive pattern 150 on the upper surface of the substrate body 110, and may be in contact with a lower connecting pad 168 on a lower surface of the substrate body 110. The connection vias 120 may not overlap the semiconductor chip 200. The connection vias 120 may include a greater number than that illustrated. The connection vias 120 may include at least one metal of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C), or alloys formed of two or more metals thereof. In an example embodiment, unlike the one illustrated, the package substrate 100 may include internal patterns and internal vias formed in a plurality of layers within the substrate body 110, and the internal patterns and internal vias may replace the connection vias 120.

The upper protective layer 130 and the lower protective layer 140 may be solder resist layers protecting the substrate body 110, the conductive patterns 150, and the lower connecting pads 168 from external physical and chemical damage. The upper protective layer 130 may cover the upper surface of the substrate body 110, and may cover a portion of the conductive patterns 150. The upper protective layer 130 may cover an upper surface of the via connection structure 158. The upper protective layer 130 may expose a region in which the semiconductor chip 200 of the substrate body 110 is mounted. The upper protective layer 130 may be spaced apart from an alignment-inducing structure 155, and may not be in contact with the alignment-inducing structure 155. The lower protective layer 140 may cover the lower surface of the substrate body 110, and may cover the lower connection pads 168. The lower protective layer 140 may expose at least portions of lower surfaces of each of the lower pads 160. The upper protective layer 130 and the lower protective layer 140 may include an insulating material, and may include, for example, prepreg, ABF, FR-4, BT, or photo solder resist (PSR).

The conductive patterns 150 may be disposed on the upper surface of the substrate body 110. The conductive patterns 150 may extend on the upper surface of the substrate body 110 in a horizontal direction. The conductive patterns 150 may be electrically connected to a chip body 210 of the semiconductor chip 200 through connection bumps 220 of the semiconductor chip 200. In an example embodiment, the conductive patterns 150 may include a ground (GND) pattern, a power (PWR) pattern, and a signal (Signal: S) pattern. Here, the signal (S) pattern may provide a transmission path for various signals, such as a data signal, excluding the ground (GND) pattern and the power (PWR) pattern. In an example embodiment, the conductive patterns 150 may extend from a region overlapping the semiconductor chip 200 to a region not overlapping the semiconductor chip 200. In an example embodiment, the conductive patterns 150 may extend in the Y-direction in the region overlapping the semiconductor chip 200, and may extend in various horizontal directions on an X-Y plane, such as the X-direction, in the region not overlapping the semiconductor chip 200. The conductive pattern 150 may include a greater or fewer number than those illustrated. The conductive pattern 150 may have a first side surface and a second side surface opposite the first side surface. In an example embodiment, the conductive pattern 150 may include a first type conductive pattern 150 disposed in the region overlapping the semiconductor chip 200, and a second type conductive pattern 150 intersecting the region overlapping the semiconductor chip 200, and a first type conductive pattern 150_1 and a second type conductive pattern 150_2 may be disposed alternately. In an example embodiment, the second type conductive pattern 150_2 may be a ground pattern or a power pattern. The first type conductive pattern 150_1 may include a via connection structure 158 disposed in one end not overlapping the semiconductor chip 200, and may include an alignment-inducing structure 155 disposed in one end overlapping the semiconductor chip 200. The second type conductive pattern 1502 may include a via connection structure 158 disposed in both ends or one end, and may include an alignment-inducing structure 155 disposed in the region overlapping the semiconductor chip 200. In an example embodiment, each of the first type conductive pattern 150_1 and the second type conductive pattern 150_2 may include an alignment-inducing structure 155. In an example embodiment, the first type conductive pattern 150_1 may include one alignment-inducing structure 155 and one via connection structure 158, and the second type conductive pattern 1502 may include two alignment-inducing structures 155 and two via connection structures 158, but the number of alignment-inducing structures 155 and via connection structures 158 that each of the first type conductive pattern 150_1 and the second type conductive pattern 150_2 may include is not limited thereto. In an example embodiment, some of the conductive patterns 150 may not include the alignment-inducing structure 155 or the via connection structure 158. The conductive patterns 150 may be disposed so that the alignment-inducing structures 155 respectively included therein are disposed parallel in the first direction (e.g., the Y-direction). The alignment-inducing structure 155 may be disposed in two rows, but the present disclosure is not limited thereto. In an example embodiment, the alignment-inducing structure 155 may be disposed in one row or three or more rows. The conductive patterns 150 may include at least one metal material, among aluminum (Al), copper (Cu), nickel (Ni), tungsten (W), platinum (Pt), and gold (Au), but the present disclosure is not limited to.

As illustrated in FIG. 2A, FIG. 2C and FIG. 3, the alignment-inducing structure 155 may include a center portion 151 and indentation portions 152. The principle of the alignment-inducing structure 155 aligning the connection bumps 220 to align the semiconductor chip 200 has been described in detail in the description of a manufacturing method. The center portion 151 may be disposed between a pair of indentation portions 152. The center portion 151 may be defined as a portion having a width equal to a width T of the conductive pattern 150 between the indentation portions 152. The indentation portion 152 may be defined as a portion having a width less than the width T of the conductive pattern 150 by an indentation side surface 152s indented from one side surface of the conductive pattern 150. The indentation portion 152 may include an indentation side surface 152s indented from one side surface of the conductive pattern 150. A space in which the conductive pattern 150 is indented on the indentation side surface 152s may be defined as an indentation space 152v. An indentation width V of the indentation space 152v may be ⅓ or less of the width T of the conductive pattern 150, and a minimum width W of the indentation portion 152 may be ⅔ or more of the width T of the conductive pattern 150. When the indentation width V is ⅓ or more of the width T of the conductive pattern 150, the performance of the semiconductor package 10 may be degraded as the resistance of the conductive pattern 150 increases. That is, when the minimum width W of the indentation portion 152 is ⅔ or less of the width T of the conductive pattern 150, the performance of the semiconductor package 10 may be degraded as the resistance of the conductive pattern 150 increases. In an example embodiment, the width T of the conductive pattern 150 may be 15 μm to 25 μm, and the indentation width V may be 5 μm to 8 μm. In an example embodiment, the minimum width W of the indentation portion 152 may be 10 μm to 15 μm. Each indentation side surface 152s may include a first portion 152s1 and a second portion 152s2. In this example embodiment, the first portion 152s1 may be defined as a portion of the indentation side surface 152s, parallel to a side surface of the conductive pattern 150, and the second portion 152s2 may be defined as a portion connecting the first portion 152s1 and a side surface of the center portion 151. The second portion 152s2 may be inclined so that a width of the indentation portion 152 increases as the second portion 152s2 approaches the center portion 151. A solder 225 may overlap at least a portion of the second portion 152s2, and the solder 225 may cover at least a portion of the second portion 152s2. The solder 225 may overlap a portion of the first portion 152s1 and cover a portion of the first portion 152s1. At least a portion of the first portion 152s1 may be in contact with the encapsulant 300. A portion of the second portion 152s2 that does not contact the solder 225 may be in contact with the encapsulant 300.

A volume (V₀) of an indentation space 151v may be determined by the indentation width V, an indentation length L, and a height H of the conductive pattern 150. A sum of the volumes of a pair of indentation spaces 151v disposed on both sides of the center portion 151 may be 50% or more of the volume of the solder 225. Since the sum of the volumes of the pair of indentation spaces 151v has a size of 50% or more of the volume of the solder 225, the semiconductor chip 200 may be induced to be aligned on the conductive pattern 150. Explanations thereof will be described below in the description of the manufacturing method. In an example embodiment, the sum of the volumes of the pair of indentation spaces 151v may be 90% or less of the volume of the solder 225. When the sum of the volumes of the pair of indentation spaces 151v exceeds 90% of the volume of the solder 225, the alignment-inducing effect of the alignment-inducing structure 155 may be reduced as the flow of the solder 225 is weakened. In an example embodiment, a planar shape of the indentation space 151v may be a polygonal shape. For example, the planar shape of the indentation space 151v may be a rectangular trapezoidal shape as illustrated. When the planar shape of the indentation space 151v is a rectangular hexahedral shape, the volume (V₀) of the indentation space 151v may be calculated as

$${V}_{0} = \frac{1}{2} \{ ( L 2 ) + 2 ( L 1 ) \} \times ( V ) ( H ) .$$

Since the alignment-inducing structure 155 may include a pair of indentation spaces 151v, the volume of the indentation spaces 151v included in one alignment-inducing structure 155 may be 2V₀={(L2)+2(L1)}×(V)(H). The volume (2V₀) of the pair of indentation spaces 151v may be 50% or more of the volume (Vₛ) of the solder 225. That is, the relationship

$$\frac{1}{2} {V}_{s} < 2 {V}_{0} = \{ ( L 2 ) + ( L 1 ) \} \times ( V ) ( H )$$

may be established. This equation is an example, and the equation relationship between the volume (V₀) of the indentation space 151v and the volume (Vₛ) of the solder may be variously modified depending on the shape of the indentation space 151v, and the size and composition of the solder 225. In an example embodiment, the height H of the conductive pattern 150 may be 10 μm to 16 μm. In an example embodiment, the volume (Vₛ) of the solder may be 22,000 μm³ to 34,000 μm³. In an example embodiment, the sum of the volumes (V₀) of a pair of indentation spaces 151v may be greater than 11,000 μm³ to 17,000 μm³, which is 50% of the volume (Vₛ) of the solder.

A pair of indentation portions 152 may include a first indentation portion 152a and a second indentation portion 152b. A first indentation side surface 152sa of the first indentation portion 152a and a second indentation side surface 152sb of the second indentation portion 152b may be disposed on opposite side surfaces. That is, a first indentation space 152va and a second indentation space 152vb may be disposed on opposite side surfaces of the conductive pattern 150. A second portion 152s2a of the first indentation side surface 152sa and a second portion 152s2b of the second indentation side surface 152sb may be parallel to each other. The first indentation portion 152a, the first indentation side surface 152sa and the first indentation space 152va may have a shape that is symmetrical based on the center portion 151 with respect to the second indentation portion 152b, the second indentation side surface 152sb and the second indentation space 152vb. In an example embodiment, a separation distance D may be defined as the shortest distance between a portion having a first width Wa, which is a minimum width of the first indentation portion 152a, and a portion having a second width Wb, which is a minimum width of the second indentation portion 152b. In an example embodiment, the separation distance D may be defined as the shortest distance between a first portion 152s1a of the first indentation side surface 152sa and a first portion 152s1b of the second indentation side surface 152sb. The separation distance D may be less than a width R of the solder 225. When the separation distance D is greater than the width R of the solder 225, the solder 225 may not be in contact with one of the first indentation portion 152a and the second indentation portion 152b, which may cause the degradation of the function of the alignment-inducing structure 155.

The via connection structure 158 may be disposed in one end of the conductive pattern 150 and may be in contact with the connection via 120. The conductive pattern 150 may be electrically connected to the lower connection pad 168 through the connection via 120 connected to the via connection structure 158. The via connection structure 158 may have a greater width than other portions of the conductive pattern 150. An upper surface shape of the via connection structure 158 may be circular or elliptical, but is not limited thereto. For example, the upper surface shape of the via connection structure 158 may be a polygonal shape.

The lower pads 160 and the lower connection pads 168 may be disposed on the lower surface of the substrate body 110. The connection conductors 400 may be arranged under the lower pads 160. The lower connection pads 168 may be in contact with and connected to the connection vias 120. The lower pads 160 may be electrically connected to the lower connection pads 168 through interconnection lines disposed on the lower surface of the substrate body 110, and may be electrically connected to the conductive pattern 150 on the upper surface of the substrate body 110 through the connection vias 120 on the lower connection pads 168. The lower pads 160 and the lower connection pads 168 may include a greater or fewer number than that illustrated. The lower pads 160 and the lower connection pads 168 may include at least one metal material, for example, aluminum (Al), copper (Cu), nickel (Ni), tungsten (W), platinum (Pt), and gold (Au), but the present disclosure is not limited thereto.

The semiconductor chip 200 may be mounted on the package substrate 100 in a flip-chip bonding manner. In FIG. 1B and the like, one semiconductor chip 200 is illustrated, but, according to an example embodiment, the semiconductor chip 200 may include a plurality of semiconductor chips 250 stacked in a vertical direction (e.g., in a Z-direction). The semiconductor chip 200 may be electrically connected to the conductive patterns 150 through the connection bumps 220. The semiconductor chip 200 may be a memory chip including memory circuits such as a volatile memory such as dynamic RAM (DRAM), static RAM (SRAM), and the like, and a nonvolatile memory such as a phase change RAM (PRAM), a magnetic RAM (MRAM), a resistive RAM (RRAM), and a flash memory. In an example embodiment, the semiconductor chip 200 may be a logic chip including logic circuits such as a central processor unit (CPU), a graphics processor unit (GPU), a field programmable gate array (FPGA), an application processor (AP), a digital signal processor, an encryption processor, a microprocessor, a microcontroller, an analog-to-digital converter, and an application-specific IC (ASIC). The semiconductor chip 200 may include a chip body 210 and connection bumps 220 disposed below the chip body 210.

The chip body 210 may include a memory circuit or a logic circuit, and may have a front surface and a rear surface opposite to the front surface on which the connection bumps 220 are disposed. The front surface of the chip body 210 may be referred to as a lower surface, and the rear surface of the chip body 210 may be referred to as an upper surface. The chip body 210 may include a long axis and a short axis. A width of the chip body 210 in a first direction (e.g., X-direction) may be greater than a width in a second direction (e.g., Y-direction).

The connection bumps 220 may be disposed below the lower surface of the chip body 210. The connection bumps 220 may be in contact with and electrically connected to the conductive patterns 150. The connection bumps 220 may include a greater or fewer number than that illustrated. Each of the connection bumps 220 may include a pillar 221 and a solder 225 below the pillar 221. The pillar 221 may include copper (Cu) or alloys of copper (Cu). The pillar 221 may be in contact with the lower surface of the chip body 210 and may be spaced apart from the conductive pattern 150. The solder 225 may include a low melting point metal, for example, tin (Sn) or alloys including tin (Sn) (Sn—Ag—Cu). The solder 225 may be a solder ball and may be in direct contact with the alignment-inducing structure 155. The solder 225 may cover an upper surface and side surfaces of the center portion 151 of the alignment-inducing structure 155, and may fill at least a portion of the indentation spaces 152v. The solder 225 may cover at least portions of the indentation side surfaces 152s. The width R of the solder 225 may be greater than the width T of the conductive pattern 150. The width R of the solder 225 may be greater than the separation distance D. The solder 225 may be in contact with the upper surface of the substrate body 110. A side edge of the solder 225 may not overlap the center portion 151 and may include a portion overlapping the indentation portion 152. A portion of an edge of a portion in which the solder 225 is in contact with the conductive pattern 150 may be in contact with the indentation portion 152. As the solder 225 is aligned by the alignment-inducing structure 155, the semiconductor chip 200 itself may be aligned on the conductive patterns 150, which is described in detail in the description of the manufacturing method.

The encapsulant 300 may surround the semiconductor chip 200 on the package substrate 100. The encapsulant 300 may encapsulate at least a portion of the semiconductor chip 200. An upper surface of the encapsulant 300 may be disposed on a higher level than an upper surface of the semiconductor chip 200. An external surface of the encapsulant 300 may be coplanar with an external surface of the package substrate 100. The encapsulant 300 may be in contact with a portion of the conductive patterns 150 not covered by the upper protective layer 130. A portion of the alignment-inducing structure 155 that does not come into contact with the connection bump 220 may be in contact with the encapsulant 300. In an example embodiment, when an underfill is disposed below the semiconductor chip 200, the encapsulant 300 may include the underfill. The encapsulant 300 may include, for example, a thermosetting resin such as an epoxy resin, a thermoplastic resin such as a polyimide, or a prepreg, ABF, FR-4, BT and an Epoxy Molding Compound (EMC), in which an inorganic filler is impregnated in these resins.

The connection conductors 400 may be disposed below the package substrate 100. The connection conductors 400 may be disposed below the lower pads 160 of the package substrate 100. The connection conductors 400 may electrically connect the lower pads 160, the lower connecting pads 168 connected to the lower pads 160, the connection vias 120 and the conductive patterns 150 to the semiconductor chip 200. The semiconductor package 10 may be connected to an external device through the connection conductors 400. The connection conductors 400 may have a spherical shape or an oval shape formed of a low-melting point metal such as tin (Sn), indium (In), bismuth (Bi), antimony (Sb), copper (Cu), silver (Ag), zinc (Zn) and lead (Pb), or alloys containing these metals (e.g., Sn—Ag—Cu).

In the description of example embodiments below, any description overlapping the description described above with reference to FIGS. 1A to 3 will be omitted.

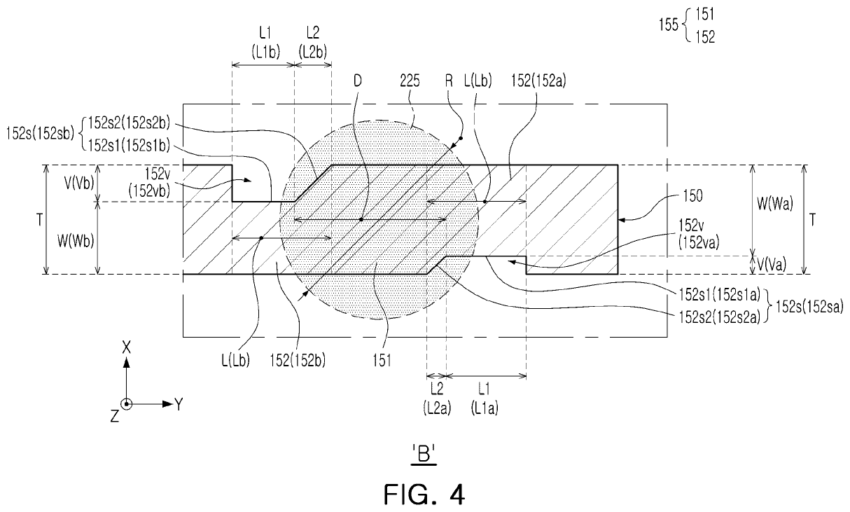

FIGS. 4 to 7 are schematic plan enlarged views illustrating a semiconductor package according to example embodiments. FIGS. 4 to 7 illustrate regions corresponding to FIG. 2C.

Referring to FIG. 4, unlike an example embodiment of FIG. 2C, a first indentation portion 152a and a second indentation portion 152b may have different shapes. For example, a first indentation width Va may be less than a second indentation width Vb, and the first width Wa of the first indentation portion 152a may be greater than the second width Wb of the second indentation portion 152b. In a process of manufacturing the semiconductor package, the size, volume and shape of a first indentation space 152va and the second indentation space 152vb may be variously modified depending on the direction and degree of misalignment of the solder 225 on the conductive pattern 150. A second portion 152s2a of a first indentation side surface 152sa and a second portion 152s2b of the second indentation side surface 152sb may be parallel to each other. In this example embodiment as well, for the alignment of the semiconductor chip 200, the sum of the volume (V₁) of the first indentation space 152va and the volume (V₂) of the second indentation space 152vb may be 50% or more of the volume (Vₛ) of the solder. Referring to FIG. 3 together, an equation regarding the relationship between the volume (V₁) of the first indentation space 152va, the volume (V₂) of the second indentation space 152vb, and the volume (Vₛ) of the solder 225 may be as follows.

$$\frac{1}{2} {V}_{s} < {V}_{1} + {V}_{2} = \frac{1}{2} \{ ( L 2 a ) + 2 ( L 1 a ) \} \times ( Va ) ( H ) + \frac{1}{2} \{ ( L 2 b ) + 2 ( L 1 b ) \} \times ( Vb ) ( H ) .$$

Since this equation is based on the assumption that plane cross-sectional shapes of the first indentation space 152va and the second indentation space 152vb are trapezoidal, the equation may be modified depending on the shapes of the first indentation space 152va and the second indentation space 152vb.

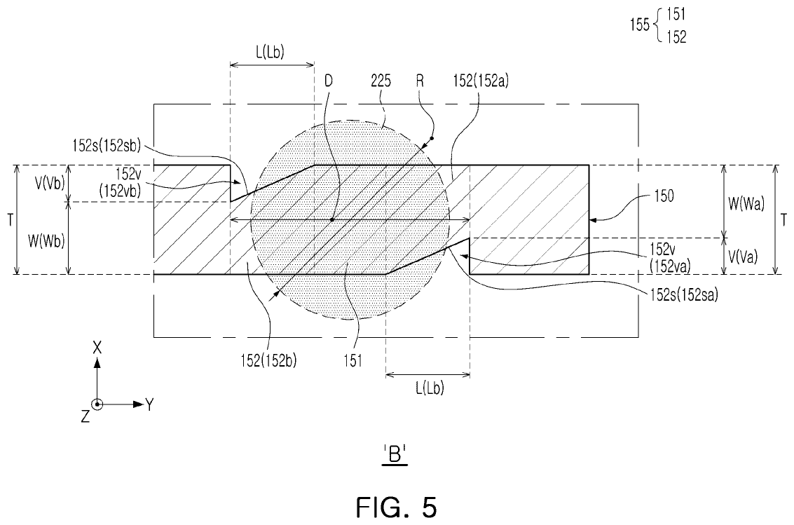

Referring to FIG. 5, unlike the example embodiment of FIG. 2C, the plane cross-sectional shape of the indentation space 152v may be a right triangle shape. The indentation side surface 152s, which is a hypotenuse portion of the right triangle shape, may overlap a side edge of a solder 255, and may be in contact with the solder 255. The first indentation side surface 152sa and the second indentation side surface 152sb may be parallel to each other. In an example embodiment, for the alignment of the semiconductor chip 200, the sum of the volume (V₀) of the indentation space 152v may be 50% or more of the volume (Vₛ) of the solder. Referring to FIG. 3 together, an equation for a relationship between the volume (V₀) of the indentation space 152v and the volume (Vₛ) of the solder 225 may be as follows. ½Vₛ<2V₀=(L)(V)(H). Since this equation is based on the assumption that plane cross-sectional shapes of the first indentation space 152va and the second indentation space 152vb are triangles having the same size, the equation may be modified depending on the shape of the first indentation space 152va and the second indentation space 152vb. In an example embodiment, as in the example embodiment of FIG. 4, the first indentation space 152va and the second indentation space 152vb may have different shapes or sizes.

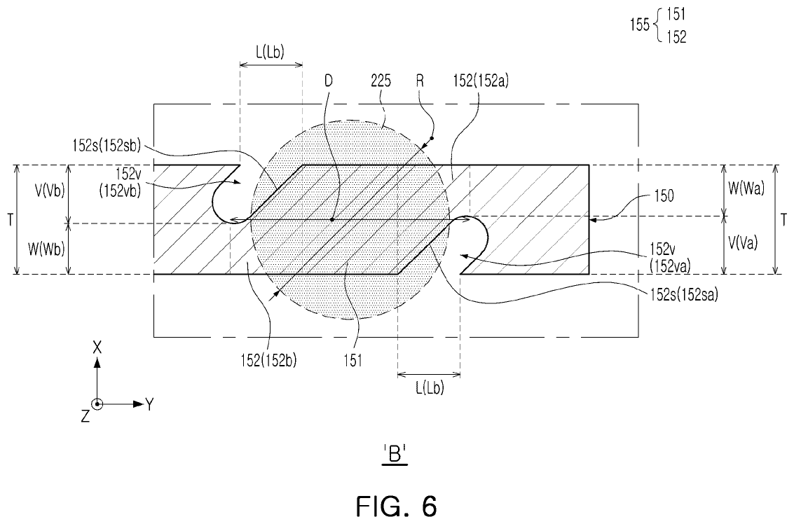

Referring to FIG. 6, unlike the example embodiment of FIG. 2C, plane cross-sectional shapes of the first indentation space 152va and the second indentation space 152vb may have a partially rounded shape. That is, the first indentation side surface 152sa and the second indentation side surface 152sb may include a portion having a curvature. Within a range in which the sum of the volumes (V₀) of a pair of indentation spaces 152v is 50% or more of the volume (Vₛ) of the solder 225, the shape and size of the indentation space 152v may be variously modified. The first indentation side surface 152sa and the second indentation side surface 152sb may partially include portions parallel to each other.

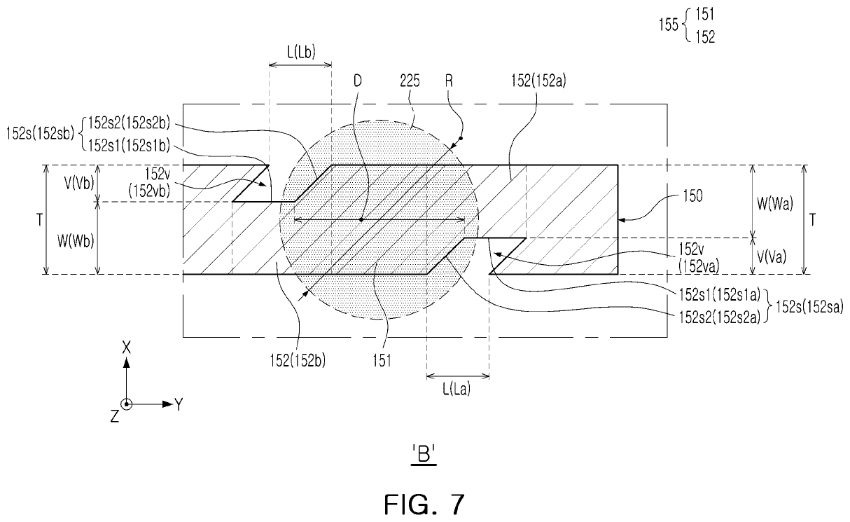

Referring to FIG. 7, unlike the example embodiment of FIG. 2C, plane cross-sectional shapes of the first indentation space 152va and the second indentation space 152vb may have a parallelogram shape. The second portion 152s2a of the first indentation side surface 152sa and the second portion 152s2b of the second indentation side surface 152sb may be parallel to each other. In an example embodiment as well, for the alignment of the semiconductor chip 200, the sum of the volumes (V₀) of the indentation spaces 152v may be 50% or more of the volume (Vₛ) of the solder, and referring also to FIG. 3, the following equation may be applied between the volume (V₀) of each indentation space 152v and the volume (Vₛ) of the solder.

$$\frac{1}{2} {V}_{s} < 2 {V}_{0} = 2 ( L ) ( V ) ( H ) .$$

The description with reference to FIGS. 4 to 7 relates to an example embodiment of the present disclosure, and the shape of the alignment-inducing structure 155 may be variously modified, and the shapes of various example embodiments may be combined within a compatible range.

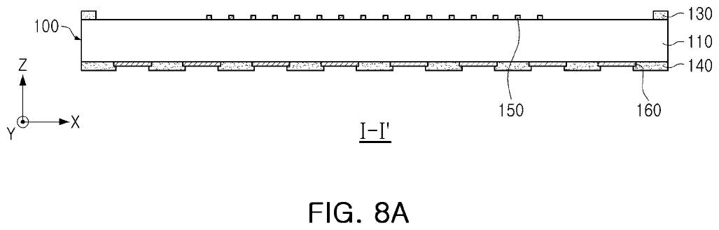

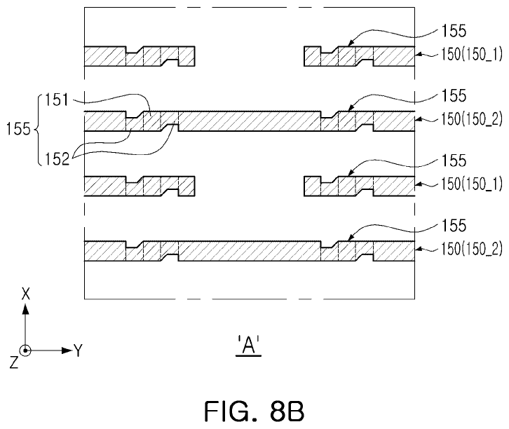

FIGS. 8A, 9A, 10A, 11A and 12 are cross-sectional views illustrating a method of manufacturing a semiconductor package according to example embodiments according to a process sequence. FIGS. 8A, 9A, 10A, 11A and 12 illustrate regions corresponding to FIG. 1B.

FIGS. 8B, 9B, 10B, and 11B are enlarged plan views illustrating a method of manufacturing a semiconductor package according to example embodiments according to a process sequence. FIGS. 8B, 9B, 10B and 11B illustrate regions corresponding to FIG. 2A.

Referring to FIGS. 8A and 8B, a package substrate 100 including a substrate body 110 on which an upper protective layer 130, a lower protective layer 140, conductive patterns 150 and lower pads 160 are disposed may be prepared.

In an example embodiment, depending on the type of the package substrate 100, the connection vias 120 of FIG. 1C may be formed within the package substrate 100, or a plurality of internal patterns disposed on different levels and internal vias connecting the internal patterns disposed on different levels to each other may be formed. The conductive patterns 150 may include first type conductive patterns 150_1 and second type conductive patterns 150_2. In an example embodiment, the first type conductive patterns 150_1 and the second type conductive patterns 150_2 may be disposed alternately. The conductive patterns 150 may be formed to include an alignment-inducing structure 155. Referring to FIG. 1B and FIG. 2A together, the alignment-inducing structure 155 may be formed in the connection bumps 220 of the semiconductor chip 200, specifically, in a portion in which the solder 225 of the connection bumps 220 is to be disposed. Referring to FIG. 2C together, in order to prevent performance degradation of the semiconductor package 10 due to an increase in the resistance of the conductive pattern 150, an indentation width V may be formed to be ⅓ or less of the width T of the conductive pattern 150. In an example embodiment, the conductive patterns 150 may be formed to include the alignment-inducing structure 155 from the beginning. In an example embodiment, the conductive patterns 150 may be formed in a horizontally extending bar shape, and then the conductive patterns 150 may be partially etched to have an alignment-inducing structure 155 and may thus be formed to have a shape partially indented from a side surface thereof.

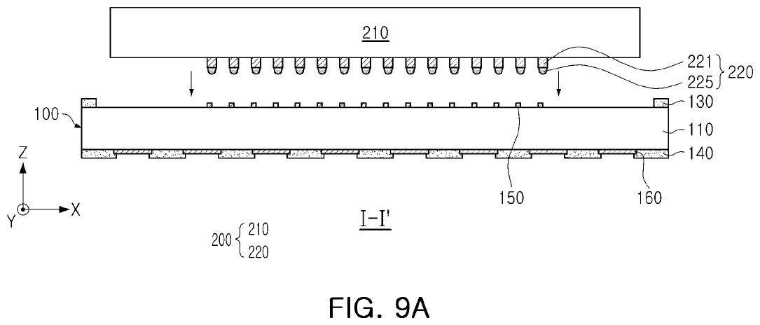

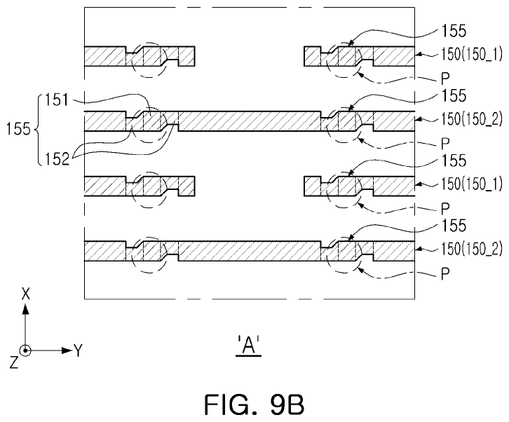

Referring to FIGS. 9A and 9B, in order to mount the semiconductor chip 200 on the package substrate 100, the semiconductor chip 200 may be disposed on the package substrate 100.

In order to mount the semiconductor chip 200 in a flip-chip manner, the semiconductor chip 200 including connection bumps 220 may be disposed on the package substrate 100. The semiconductor chip 200 may be disposed so that the connection bumps 220 face the package substrate 100. Solder disposition regions P of FIG. 9B represent regions overlapping the solder 225 included in the connection bumps 220 of the semiconductor chip 200 of FIG. 9A. As in FIG. 9B, the solder disposition regions P may be misaligned with the conductive patterns 150.

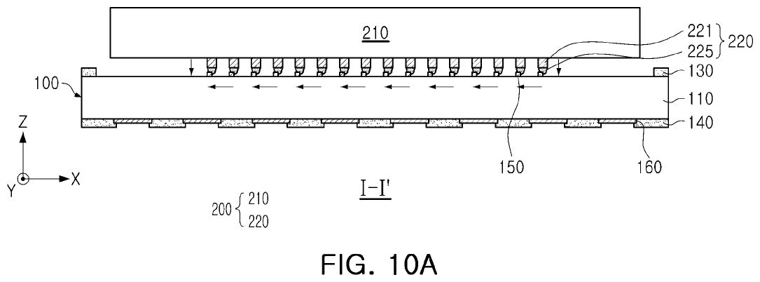

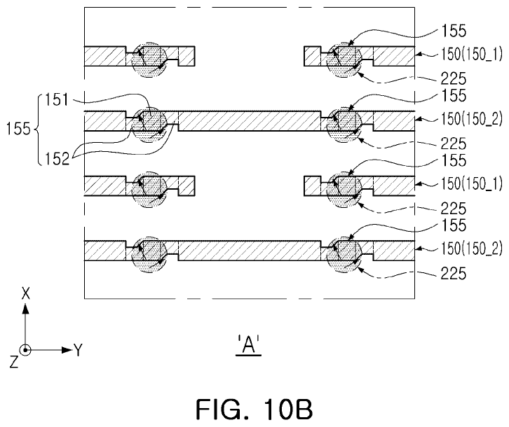

Referring to FIGS. 10A and 10B, the connection bumps 220 may be bonded on the conductive patterns 150.

In a process of mounting the semiconductor chip 200, the solders 225 may be disposed on the alignment-inducing structure 155 of the conductive patterns 150. The solders 225 may be melted by a reflow process and may be attached to a surface of the alignment-inducing structure 155. When the alignment-inducing structure 155 does not exist, the connection bumps 220 may be bonded in a misaligned state with the conductive patterns 150, and contact defects may occur, such as a decrease in a contact area between the solders 225 and the conductive patterns 150 or a single solder 225 coming into contact with multiple conductive patterns 150. Referring to FIG. 2C together, the present disclosure may include the alignment-inducing structure 155, so that each solder 225 may be partially melted and guided into the indentation space 152v by surface tension, and the solder 225 may be guided in a direction of an arrow illustrated in FIG. 10B. When the volume of the indentation space 152v is not sufficient, only a portion of the solder 225 may be guided into the indentation space 152v, and the semiconductor chip 200 itself may not be aligned together. In the present disclosure, the sum of the volumes (V₀) of a pair of indentation spaces 152v included in the alignment-inducing structure 155 may be formed to be 50% or more of the volume (Vₛ) of the solder 225, so that the semiconductor chip 200 itself may also be aligned together as the solder 225 is aligned by the alignment-inducing structure 155. That is, the semiconductor chip 200 may be guided and aligned in a direction of an arrow in FIG. 10A. In an example embodiment, the sum of the volumes of a pair of indentation spaces 151v may be 90% or less of the volume of the solder 225. When the sum of the volumes of a pair of indentation spaces 151v exceeds 90% of the volume of the solder 225, the alignment-inducing effect of the alignment-inducing structure 155 may be reduced as the flow of the solder 225 becomes weak.

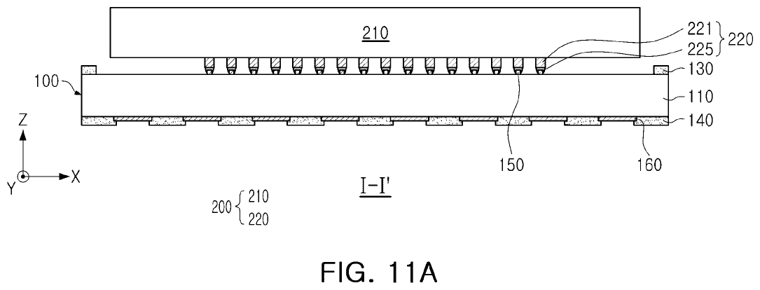

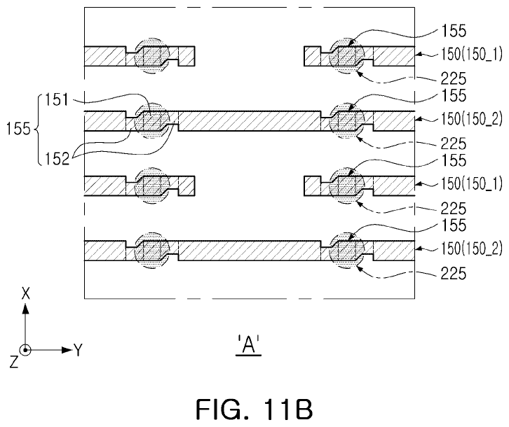

Referring to FIGS. 11A and 11B, a semiconductor chip 200 may be mounted on a package substrate 100.

By the alignment-inducing structure 155, the solders 225 included in the connection bumps 220 of the semiconductor chip 200 may be aligned on the alignment-inducing structure 155, so that the semiconductor chip 200 may be mounted in a correct position without a separate additional alignment process.

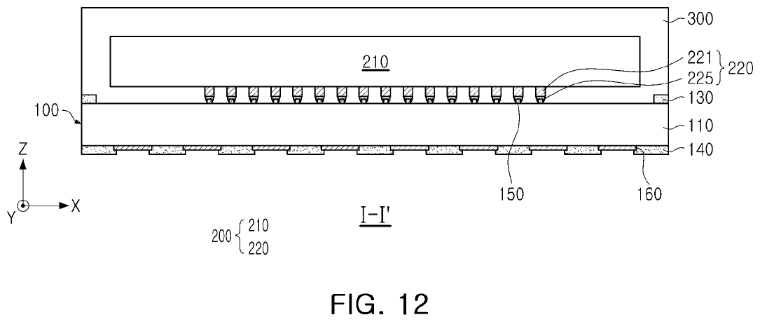

Referring to FIG. 12, an encapsulant 300 encapsulating at least a portion of the semiconductor chip 200 may be formed.

The encapsulant 300 may be formed to cover at least a portion of the semiconductor chip 200 on the package substrate 100. The encapsulant 300 may be formed, for example, by applying and curing EMC. In an example embodiment, an underfill layer may be formed below the semiconductor chip 200 using a CUF process before forming the encapsulant 300. In an example embodiment, the encapsulant 300 may be partially removed from an upper surface thereof by a method such as grinding. In an example embodiment, the encapsulant 300 may be partially removed from the upper surface thereof so that the upper surface of the semiconductor chip 200 is exposed. Referring to FIG. 1B together, connection conductors 400 may be formed below the lower pads 160 of the package substrate 100, and the semiconductor package 10 of FIG. 1B may be manufactured.

The present disclosure is not limited to the above-described embodiments and the accompanying drawings but is defined by the appended claims. Therefore, those of ordinary skill in the art may make various replacements, modifications, or changes, and combinations of example embodiments without departing from the scope of the present disclosure defined by the appended claims, and these replacements, modifications, or changes should be construed as being included in the scope of the present disclosure.

What is claimed is:

1. A semiconductor package, comprising:
a package substrate including a substrate body and a conductive pattern on an upper surface of the substrate body;
a semiconductor chip on the package substrate, and including a chip body and a connection bump below the chip body, the connection bump including a pillar and a solder below the pillar;
an encapsulant surrounding the semiconductor chip on the package substrate; and
connection conductors below the package substrate and electrically connected to the conductive pattern,
wherein the conductive pattern includes an alignment-inducing structure overlapping the semiconductor chip,
wherein the alignment-inducing structure includes:
a first indentation portion indented on a first side surface of the conductive pattern;
a second indentation portion indented on a second side surface of the conductive pattern opposite to the first side surface, and spaced apart from the first indentation portion in a longitudinal direction of the conductive pattern; and
a center portion between the first indentation portion and the second indentation portion, and
wherein the solder covers at least portions of each of an upper surface and side surfaces of the center portion, and is disposed in at least a portion of a space indented by each of the first indentation portion and the second indentation portion.

2. The semiconductor package of claim 1,
wherein a volume of the space indented by the first indentation portion and the second indentation portion is 50% or more of a volume of the solder.

3. The semiconductor package of claim 1,
wherein the solder covers at least portions of each of a first indentation side surface of the first indentation portion and a second indentation side surface of the second indentation portion.

4. The semiconductor package of claim 1,
wherein a distance by which the first indentation portion and the second indentation portion are spaced apart from each other in the longitudinal direction of the conductive pattern is less than a width of the solder in the longitudinal direction.

5. The semiconductor package of claim 1,
wherein a side edge of the solder is spaced apart from the center portion.

6. The semiconductor package of claim 1,
wherein a width of the solder is greater than a width of the conductive pattern.

7. The semiconductor package of claim 1,
wherein the first indentation portion and the second indentation portion include a portion having an inclined side surface so that a width thereof increases as the first indentation portion and the second indentation portion approach the center portion.

8. The semiconductor package of claim 1,
wherein the center portion is defined as a portion having a uniform width between the first indentation portion and the second indentation portion.

9. The semiconductor package of claim 1,
wherein the solder is in contact with the upper surface of the substrate body.

10. The semiconductor package of claim 1,
wherein the conductive pattern extends in a horizontal direction, and
the conductive pattern further includes a via connection structure disposed in one end not overlapping the semiconductor chip.

11. The semiconductor package of claim 10,
wherein the package substrate further includes a via penetrating through the substrate body below the via connection structure.

12. The semiconductor package of claim 1,
wherein the package substrate further includes an upper protective layer covering a portion of the upper surface of the substrate body, and
the upper protective layer exposes at least the alignment-inducing structure of the conductive pattern.

13. The semiconductor package of claim 1,
wherein the package substrate further includes an upper protective layer covering a portion of the upper surface of the substrate body, and
the upper protective layer is spaced apart from the solder.

14. The semiconductor package of claim 1,
wherein each of a first indentation width of the first indentation portion and a second indentation width of the second indentation portion is equal to or less than ⅓ of a width of the conductive pattern.

15. A semiconductor package, comprising:
a semiconductor chip including a connection bump below a lower surface;
a package substrate below the semiconductor chip, and including a conductive pattern extending in a horizontal direction; and
an encapsulant surrounding the semiconductor chip on the package substrate,
wherein the conductive pattern further includes an alignment-inducing structure in contact with the connection bump, and
wherein alignment-inducing structure includes:
a center portion having a first width; and
an indentation portion including a portion having a width less than the first width,
wherein a portion of the indentation portion is in contact with the encapsulant.

16. The semiconductor package of claim 15,
wherein a minimum width of the indentation portion is greater than ⅔ of the first width.

17. The semiconductor package of claim 15,
wherein another portion of the indentation portion is in contact with the connection bump.

18. The semiconductor package of claim 15,
wherein a minimum width of the indentation portion is a second width,
the first width is 15 μm to 25 μm, and
the second width is 10 μm to 15 μm.

19. A semiconductor package, comprising:
a substrate body;
a plurality of conductive patterns on an upper surface of the substrate body, and including an alignment-inducing structure;
a semiconductor chip on the plurality of conductive patterns, and electrically connected to the plurality of conductive patterns through a plurality of connection bumps; and
connection conductors below the substrate body,
wherein the plurality of conductive patterns include a first type conductive pattern in which one end thereof is disposed in a region overlapping the semiconductor chip, and a second type conductive pattern extending by intersecting a region overlapping the semiconductor chip,
the first type conductive pattern includes the alignment-inducing structure disposed adjacently to the one end,
the second type conductive pattern includes two or more alignment-inducing structures disposed in a portion intersecting the region overlapping the semiconductor chip,
each of the plurality of connection bumps is in contact with the alignment-inducing structure of the first type conductive pattern or the second type conductive pattern, and
the alignment-inducing structure includes a pair of indentation side surfaces disposed to be misaligned from each other on both side surfaces opposing each other in a lateral direction of the plurality of conductive patterns.

20. The semiconductor package of claim 19,
wherein a corresponding one of the plurality of connection bumps is in contact with the pair of indentation side surfaces.
